(19) United States
(12) Patent Application Publication
(10) Pub. No.: US 2025/0012734 A1
(43) Pub. Date: Jan. 9, 2025

(54) Multiple Pass Optical Measurements Of Semiconductor Structures

(71) Applicant: KLA Corporation, Milpitas, CA (US)

(72) Inventors: Zhengquan Tan, Cupertino, CA (US); Houssam Chouaib, Milpitas, CA (US); Anderson Chou, Hillsboro, OR (US)

(21) Appl. No.: 18/743,118

(22) Filed: Jun. 14, 2024

Related U.S. Application Data
(60) Provisional application No. 63/525,170, filed on Jul. 6, 2023.
(60) Provisional application No. 63/525,967, filed on Jul. 11, 2023.
(60) Provisional application No. 63/528,057, filed on Jul. 20, 2023.
(60) Provisional application No. 63/530,706, filed on Aug. 4, 2023.

(51) Int. Cl. G01N 21/95; G01N 21/88; H01L 21/66

(52) U.S. Cl. CPC G01N 21/9501; G01N 21/8806; G01N 21/8851; H01L 22/12

(57) ABSTRACT

Methods and systems for performing multiple pass optical measurements of semiconductor structures are presented herein. A measurement beam is incident on the surface of a semiconductor wafer more than once. In some embodiments, the measurement beam is incident multiple times at the same measurement site on the semiconductor wafer in an optical path between the illumination source and the detector. In some other embodiments, the measurement beam is incident at different measurement sites on the semiconductor wafer in an optical path between the illumination source and the detector. In these embodiments, an instance of the same nominal structure under measurement is fabricated at each different measurement site. In a further aspect, an optical modulation element is disposed in the measurement path. In another further aspect, multiple pass measurements using different combinations of optical modulation targets are combined in a multi-target measurement to further enhance measurement sensitivity and break correlations.

### TECHNICAL FIELD

The described embodiments relate to metrology systems and methods, and more particularly to methods and systems for improved measurement of semiconductor structures.

### BACKGROUND INFORMATION

Semiconductor devices such as logic and memory devices are typically fabricated by a sequence of processing steps applied to a specimen. The various features and multiple structural levels of the semiconductor devices are formed by these processing steps. For example, lithography among others is one semiconductor fabrication process that involves generating a pattern on a semiconductor wafer. Additional examples of semiconductor fabrication processes include, but are not limited to, chemical-mechanical polishing, etch, deposition, and ion implantation. Multiple semiconductor devices may be fabricated on a single semiconductor wafer and then separated into individual semiconductor devices.

Metrology processes are used at various steps during a semiconductor manufacturing process to detect defects on wafers to promote higher yield. Optical metrology techniques offer the potential for high throughput without the risk of sample destruction. A number of optical metrology based techniques including scatterometry and reflectometry implementations and associated analysis algorithms are commonly used to characterize critical dimensions, film thicknesses, composition, overlay and other parameters of nanoscale structures.

As devices (e.g., logic and memory devices) move toward smaller nanometer-scale dimensions, characterization becomes more difficult. Devices incorporating complex three-dimensional geometry and materials with diverse physical properties contribute to characterization difficulty. In general, semiconductor device shapes and profiles are changing dramatically along with new process capabilities. In particular, advanced logic and memory devices must meet increasingly demanding specifications for Critical Dimension (CD) profiles. Thus, detailed features of geometric profiles must be measured accurately.

Significant advances in process chemistry have enabled new etch applications. In some examples, High Aspect Ratio (HAR) etch tools are capable of etching away very narrow vertical channels in semiconductor die with aspect ratios, i.e., ratio of height/width, of 80:1, or higher. This capability has enabled flash memory architectures to transition from two dimensional floating-gate architectures to fully three dimensional geometries. In some examples, film stacks and etched structures are very deep (e.g., three micrometers in depth, or more) and include an extremely high number of layers (e.g., 400 layers, or more).

As the etch process penetrates deeper into the structure, the etch rate is susceptible to change along the channel. This leads to a non-uniform etch profile, i.e., the Critical Dimension (CD) of a fabricated channel varies as a function of height. Typical semiconductor devices include millions of HAR channels separated from each other by extremely small distances, e.g., tens of nanometers. Thus, etch profile uniformity and parallelism of HAR channels must be controlled to very tight specifications to achieve an acceptable device yield.

High aspect ratio structures create challenges for film and CD measurements. The ability to measure the critical dimensions that define the shapes of holes and trenches of these structures is critical to achieve desired performance levels and device yield. The metrology must be capable of measuring the CD of a continuous profile through a deep channel to determine the location of CD variations and inflection points of profile variations.

In other examples, the most advanced memory and logic device structures, e.g., nanowire structures, forksheet structures, complementary field effect transistor (CFET) structures, multi-deck VNAND structures, etc., incorporate new complex three-dimensional geometry, dramatic topographic changes, and materials with diverse orientation and physical properties. These advanced devices are difficult to characterize.

In summary, measurement accuracy, precision, and stability are degraded due to low sensitivity to parameters of interest such as CD, shape, and film thickness, and high correlation among the parameters of interest. The problem is increasing in severity as logic and memory device features continue to scale to smaller and smaller dimensions.

X-ray based methods such as X-ray Photoemission Spectroscopy (XPS) and X-ray Fluorescence (XRF) perform atomic counts in thin films to determine thickness or composition. These measurements are slow, e.g., each measurement point requires multiple seconds, compared with optically based measurement techniques. Thus, many of the X-ray techniques are not applicable to high-volume measurement applications in a semiconductor manufacturing facility. Furthermore, some X-ray based measurement methods suffer from poor contrast, particularly in measurement applications where two or more layers include the same element, e.g., stacked layers of Titanium Nitride (TiN) and Titanium (Ti) of a Gate-All-Around (GAA) device, and stacked layers of Zirconium oxide and aluminum oxide of a DRAM capacitor device.

Existing high throughput optical metrology tools manufactured by KLA Corporation include the SpectraShape™ SS10k, SS11K, and SS12k tools focused on critical dimension and shape metrology, and SpectraFilm™ F1 and F10 tools focused on film metrology. Spectroscopic ellipsometry based measurement tools, such as the SpectraFilm™ F1 and SpectraFilm™ F10 tools, are employed to measure thickness and composition, e.g., thickness of high-K dielectric films and metal gate structures, dipole-doping layer composition, etc.

In general, a high throughput measurement system should be able to perform the desired measurement at a particular measurement site within one second, while maintaining measurement errors within desired limits, e.g., measurement uncertainty, accuracy, precision, and tool to tool matching. Unfortunately, measurement sensitivity to ultra-thin layers is limiting many measurement applications, and currently available high-throughput optical techniques are not able to meet cutting edge process requirements.

In an attempt to overcome measurement sensitivity limitations, measurement times are lengthened to increase signal to noise ratio by averaging. However, the negative impact on measurement throughput is undesirable. In some other examples, multiple metrology targets are fabricated on a wafer and measured as part of a multi-target measurement in an attempt to break correlations among parameters of interest. However, this approach increases the complexity of the structures fabricated on the wafer, uses valuable wafer area for metrology specific targets, and in many fabrication process steps, multiple, different targets are not available because the distinguishing features have yet to be fabricated.

In summary, ongoing reductions in feature size, increasing depths and layers of structural features, and increasing use of opaque material layers impose difficult requirements on optical metrology systems. Optical metrology systems must meet high precision and accuracy requirements for increasingly complex targets at high throughput to remain cost effective. In this context, existing optical techniques have emerged as critical, performance limiting issues in the design of optical metrology systems suitable for critical dimension structures and thin films. Thus, improved metrology systems and methods to overcome these limitations are desired.

### SUMMARY

Methods and systems for performing multiple pass optical measurements of semiconductor structures are presented herein. In one aspect, the optical subsystem of a semiconductor measurement system is configured such that the measurement beam is incident on the surface of the semiconductor wafer more than once in an optical path between the illumination source and the detector. In some embodiments, the measurement beam is incident multiple times at the same measurement site on the semiconductor wafer in an optical path between the illumination source and the detector. In some other embodiments, the measurement beam is incident at different measurement sites on the semiconductor wafer in an optical path between the illumination source and the detector. In these embodiments, an instance of the same nominal structure under measurement is fabricated at each different measurement site.

Multiple pass optical measurements of semiconductor structures amplify measurement sensitivity. In general, amplified measurement signal sensitivity induced by multiple pass measurements enables greater measurement accuracy, precision, and stability, reduced measurement error, and faster measurement. In addition, amplified measurement signal sensitivity induced by multiple pass measurements enables smaller measurement box sizes, improved wafer navigation positioning accuracy and repeatability, and improved tool to tool matching compared to single pass measurements. Furthermore, measurement recipe development effort is reduced using amplified measurement signals induced by multiple pass measurements. This enables the exploration of more process and device variations, which enables more robust and production worthy measurements.

In some embodiments, multiple pass measurements are employed in semiconductor process development and production metrology of shape features, film thicknesses, material composition, material bandgap measurements, or other property changes in real time. For example, multiple pass measurements may be employed to monitor atomic layer growth in semiconductor processes, material quantity or property changes induced by chemical or biologic reactions, etc.

Multiple pass optical measurements of semiconductor structures may be incorporated into many different types of optical measurement systems employed in the semiconductor industry, including, but not limited to: spectroscopic ellipsometers, spectroscopic reflectometers, angle resolved reflectometers, single-wavelength ellipsometers, etc. Measurement signals amplified due to multiple optical passes include, but are not limited to: Mueller matrix signals, harmonic signals, reflectance signals, etc.

In a further aspect, an optical modulation element is disposed in the optical path of the measurement system. In preferred embodiments, the optical modulation element is an optical element separate from the wafer and is not a portion of the semiconductor wafer. The physical interaction between the optical modulation element and the measurement beam changes the wavefront phase and amplitude properties of the measurement beam. The addition of an optical modulation element in the measurement beam path further enhances measurement sensitivity to critical parameters, e.g., CDs, shapes, and film thicknesses, and helps to break correlations between critical parameters that lead to undesirable measurement errors, excessive computational effort, or both.

In another aspect, an optical modulation target is combined with multiple pass measurements to amplify measurement sensitivity to thickness and composition. In some embodiments, the primary target includes at least one layer of a material with a specified thickness, and the optical modulation element also includes the at least one layer of the material with the specified thickness, or a different thickness. In some of these embodiments, the optical modulation element includes the at least one layer of the material with a specified thickness that is an integer multiple of the corresponding specified thickness of the material in the primary target.

In a further aspect, multiple pass measurements using different combinations of optical modulation targets are combined in a multi-target measurement to further enhance measurement sensitivity and break correlations.

The foregoing is a summary and thus contains, by necessity, simplifications, generalizations and omissions of detail; consequently, those skilled in the art will appreciate that the summary is illustrative only and is not limiting in any way. Other aspects, inventive features, and advantages of the devices and/or processes described herein will become apparent in the non-limiting detailed description set forth herein.

### BRIEF DESCRIPTION OF THE DRAWINGS

FIG. 1 depicts an embodiment of a metrology system for performing broadband spectroscopic measurements of semiconductor structures with multiple optical passes as described herein.

FIG. 2 depicts an embodiment 180 of a combined illumination source.

FIG. 3 depicts another embodiment of a metrology system for performing broadband spectroscopic measurements of semiconductor structures with multiple optical passes as described herein.

FIG. 4 is a simplified diagram illustrative of a nanosheet based semiconductor structure 150 in one embodiment.

FIG. 5 is a simplified diagram illustrative of two instances of a nanosheet based semiconductor structure as encountered by a multiple pass measurement beam in one example.

FIG. 6 is a simplified diagram illustrative of two instances of a nanosheet based semiconductor structure separated by a layer of silicon dioxide having a thickness of 50 nanometers as encountered by a multiple pass measurement beam.

FIG. 7 is a simplified diagram illustrative of two instances of a nanosheet based semiconductor structure separated by a layer of silicon dioxide having a thickness of 100 nanometers as encountered by a multiple pass measurement beam.

FIGS. 8A-8D are plots illustrative of a simulation of the sensitivity of a number of different Mueller Matrix elements to a change in dimension of an inner spacer critical dimension by one nanometer for a number of different measurement scenarios.

FIGS. 9A-9D are plots illustrative of a simulation of the sensitivity of a number of different Mueller Matrix elements to a change in dimension of a metal gate critical dimension by one nanometer for each of the different measurement scenarios associated with FIGS. 8A-8D,

FIG. 10A is a simplified diagram illustrative of a thin film structure under measurement.

FIG. 10B is a simplified diagram illustrative of an optical modulation target employed as part of a multiple pass measurement, along with the primary depicted in FIG. 10A.

FIG. 11A is a plot illustrative of the difference in simulated spectral values associated with an alpha harmonic signal induced by a one Angstrom change in thickness of the High-K layer depicted in FIG. 10A for two measurement scenarios.

FIG. 11B is a plot illustrative of the difference in simulated spectral values associated with a beta harmonic signal induced by a one Angstrom change in thickness of the High-K layer depicted in FIG. 10A for two measurement scenarios.

FIG. 12A is a plot illustrative of the difference in simulated spectral values associated with an alpha harmonic signal induced by a one Angstrom change in thickness of the metal or oxide layer depicted in FIG. 10A for two measurement scenarios.

FIG. 12B is a plot illustrative of the difference in simulated spectral values associated with a beta harmonic signal induced by a one Angstrom change in thickness of the metal or oxide layer depicted in FIG. 10A for two measurement scenarios.

FIG. 13 is a diagram illustrative of a multi-pass, multi-target measurement model in one embodiment.

FIG. 14 illustrates a method 300 of performing measurements of semiconductor structures with multiple optical passes as described herein.

### DETAILED DESCRIPTION

Reference will now be made in detail to background examples and some embodiments of the invention, examples of which are illustrated in the accompanying drawings.

Methods and systems for performing multiple pass optical measurements of semiconductor structures are presented herein. Conventional optical measurements of semiconductor structures are performed with one optical pass of the structure under measurement, i.e., the measurement beam interrogates the structure under measurement only once in its path from the illumination source to the detector.

In one aspect, the optical subsystem of a semiconductor measurement system is configured such that the measurement beam is incident on the surface of the semiconductor wafer more than once in an optical path between the illumination source and the detector. In some embodiments, the measurement beam is incident multiple times at the same measurement site on the semiconductor wafer in an optical path between the illumination source and the detector. In some other embodiments, the measurement beam is incident at different measurement sites on the semiconductor wafer in an optical path between the illumination source and the detector. In these embodiments, an instance of the same nominal structure under measurement is fabricated at each different measurement site.

Multiple pass optical measurements of semiconductor structures amplify measurement sensitivity. To first approximation, each optical ray defined as a unique wavelength and angle of incidence is incident on the same nominal structure of interest multiple times. At each pass, new signal information adds coherently with the prior signal information encoded in the optical ray. Thus, the amplification of the measurement signal is proportional to the square of the number of passes. For example, a multiple pass optical measurement that interrogates the same instance of a structure under measurement three times, or three different instances of the same nominal structure under measurement, may increase measurement sensitivity by a factor of nine.

In general, amplified measurement signal sensitivity induced by multiple pass measurements enables greater measurement accuracy, precision, and stability, reduced measurement error, and faster measurement. In addition, amplified measurement signal sensitivity induced by multiple pass measurements enables smaller measurement box sizes, improved wafer navigation positioning accuracy and repeatability, and improved tool to tool matching compared to single pass measurements. Furthermore, measurement recipe development effort is reduced using amplified measurement signals induced by multiple pass measurements. This enables the exploration of more process and device variations, which enables more robust and production worthy measurements.

In some embodiments, multiple pass measurements are employed in semiconductor process development and production metrology of shape features, film thicknesses, material composition, material bandgap measurements, or other property changes in real time. For example, multiple pass measurements may be employed to monitor atomic layer growth in semiconductor processes, material quantity or property changes induced by chemical or biologic reactions, etc.

Multiple pass measurements of a wide range of structures are contemplated within the scope of this patent document, including, but not limited to: FinFET devices, Gate-all-around (GAA) nanosheet and nanowire devices, including structures at all transistor formation processes, including nanosheet formation, SiGe recess, Inner spacer formation, and epitaxial growth steps, logic/foundry devices fabricated in accordance with High-K and Metal Gate (HKMG) processes, DRAM devices including High-K multi-layer stacks, e.g., Zirconium oxide and aluminum oxide multilayers, and any other future devices that have nanometer-scale feature sizes.

In some embodiments, multiple pass measurements improve measurement performance in many different measurement applications, including, but not limited to: 1) scatterometry critical dimension (SCD) measurements of logic devices at etch steps of 2 nanometer and 14 angstrom process nodes, and beyond, including GAA nanosheet and nanowire device transistor formation steps at the front-end-of-line and interconnect middle-end-of-line process steps; 2) SCD measurements of DRAM devices at the 10 nanometer process node, and beyond; 3) Logic lithography CD and Focus-Dose measurements on photo-resist patterning features; 4) recipe development for DRAM in-Die Overlay (IDO) and recipe Quality Metric (QM) to track measurement robustness; 5) High-K and Metal gate (HKMG) process monitoring and control during fabrication of Logic/Foundry GAA devices at 2 nanometer GAA fabrication nodes and beyond, including dipole doping layers having only one to two mono-atomic-layers; and 6) measurement of individual layer thicknesses and composition of multi-layer Si/SiGe superlattice structures of logic/foundry GAA devices.

Multiple pass optical measurements of semiconductor structures may be incorporated into many different types of optical measurement systems employed in the semiconductor industry, including, but not limited to: spectroscopic ellipsometers, spectroscopic reflectometers, angle resolved reflectometers, single-wavelength ellipsometers, etc. Measurement signals amplified due to multiple optical passes include, but are not limited to: Mueller matrix signals, harmonic signals, reflectance signals, etc.

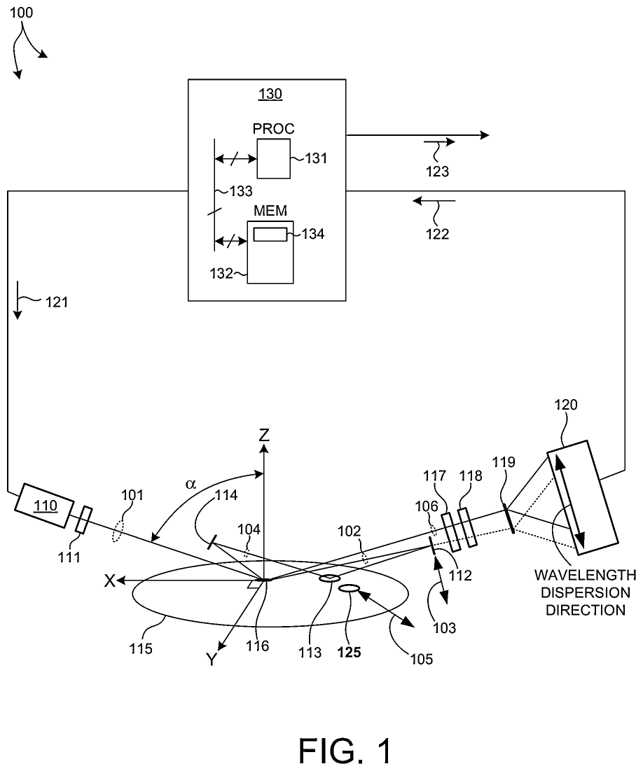

FIG. 1 depicts an exemplary, multiple pass metrology system 100 for performing broadband spectroscopic measurements of semiconductor structures (e.g., film thickness, critical dimensions, overlay, etc.). As depicted in FIG. 1, metrology system 100 is configured as an oblique incidence, broadband spectroscopic ellipsometer. However, in general, multiple pass metrology system 100 may also include additional spectroscopic ellipsometers, a spectroscopic reflectometer, scatterometer, or any combination thereof.

Metrology system 100 includes an illumination source 110 that generates a beam of illumination light 101 incident on a wafer 115. Illumination source 110 includes one or more illumination sources that emit illumination light including wavelengths in a range from 140 nanometers to 2,500 nanometers. In some examples, a single illumination source emits illumination light having wavelengths spanning a range from 170 nanometers to 900 nanometers. In some other examples, a laser sustained plasma light source emits illumination light having wavelengths spanning a range from 150 nanometers to 900 nanometers.

In some embodiments, illumination source 110 is a combined illumination source that emits illumination light in the ultraviolet, visible, and infrared spectra, including ultraviolet wavelengths down to 140 nanometers and infrared wavelengths greater than two micrometers, e.g., illumination wavelengths ranging from 140 nanometers to 2,500 nanometers. In some other embodiments, illumination source 110 is a combined illumination source that emits illumination light including wavelengths in a range from 140 nanometers to 7,000 nanometers.

In some embodiments, combined illumination source 110 includes a supercontinuum laser source and a laser sustained plasma light source. The supercontinuum laser source provides illumination at wavelengths greater than two micrometers, and in some embodiments, up to 5 micrometers, or more. The laser sustained plasma (LSP) light source (a.k.a., laser driven plasma source) produces photons spanning a wavelength range from 120 nanometers to 2500 nanometers, and beyond. The pump laser of the LSP light source may be continuous wave or pulsed. In some embodiments, combined illumination source 110 includes a supercontinuum laser source and an arc lamp, such as a Xenon arc lamp. However, a laser-driven plasma source produces significantly more photons than a Xenon lamp across the entire wavelength range from 120 nanometers to 2500 nanometers, and is therefore preferred.

In general, combined illumination source 110 includes a combination of a plurality of broadband or discrete wavelength light sources. The light generated by combined illumination source 110 includes a continuous spectrum or parts of a continuous spectrum, from ultraviolet to infrared (e.g., vacuum ultraviolet to long infrared). In general, combined illumination light source 110 may include a supercontinuum laser source, an infrared helium-neon laser source, a silicon carbide globar light source, a tungsten halogen light source, one or more infrared LEDs, one or more infrared lasers or any other suitable infrared light source generating wavelengths greater than two micrometers, and an arc lamp (e.g., a Xenon arc lamp), a deuterium lamp, a LSP light source, or any other suitable light source generating wavelengths less than two micrometers including visible and ultraviolet wavelengths.

In general, combined illumination source 110 includes multiple illumination sources optically coupled in any suitable manner. In some embodiments, light emitted by a supercontinuum laser source is directly coupled through the plasma generated by the ultraviolet/visible light source.

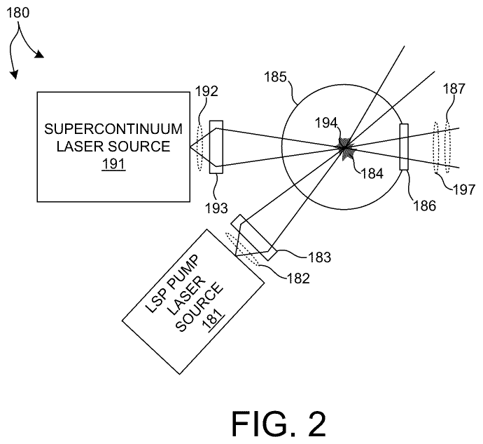

FIG. 2 depicts an embodiment 180 of a combined illumination source 110. As depicted in FIG. 2, a LSP pump laser source 181 generates pump light 182 that is focused by focusing optics 183 to sustain a plasma 184 contained by bulb 185. Plasma 184 generates broadband spectrum light over a wavelength range of ultra-violet to short infrared. Bulb 185 includes an exit port 186. LSP output light 187 is the portion of light from plasma 184 that passes through exit port 186 and is directed towards the illumination optics subsystem as described with reference to FIG. 1. In addition, supercontinuum laser source 191 generates infrared light 192 that is focused by focusing optics 193 to a focus 194 at or near plasma 184. Supercontinuum output light 197 is the portion of light from the focus 194 that passes through exit port 186 and is directed towards the illumination subsystem as described with reference to FIG. 1. In one example, the LSP output light 187 and supercontinuum output light 197 are co-located. In this manner, infrared light 197 from supercontinuum source 191 is effectively combined with ultraviolet/visible light 187 from LSP laser source 181. In one example, LSP output light 187 and supercontinuum output light 197 have the same or similar numerical aperture. In another example, LSP output light 187 and supercontinuum output light 197 have different numerical aperture. In some examples, bulb 185 is constructed from Calcium Fluoride or Magnesium Fluoride to transmit wavelengths above 2.5 micrometers generated by supercontinuum laser source 191. In some other examples, bulb 185 includes one or more exit ports 186 fabricated from Calcium Fluoride or Magnesium Fluoride to transmit wavelengths above 2.5 micrometers generated by supercontinuum laser source 191. A conventional bulb constructed from fused silica does not transmit significant light above 2.5 micrometers, and is thus unsuitable for combining light generated by the supercontinuum laser source 191 in the manner described herein. In some embodiments, the LSP pump laser source 181 is a continuous wave laser. In some other embodiments, the LSP pump laser source 181 is a pulsed laser.

As depicted in FIG. 1, metrology system 100 includes optical elements configured to direct a measurement beam incident on the surface of wafer 115 multiple times in an optical path between illumination source 110 and detector 120. In the embodiment depicted in FIG. 1, reflective elements 112 and 114 are positioned in the optical path to direct light from measurement site 116 back to measurement site 116 in a second pass.

As depicted in FIG. 1, metrology system 100 includes an illumination subsystem configured to direct illumination light 101 to one or more structures formed at measurement site 116 on wafer 115. The illumination subsystem may include any type and arrangement of optical filter(s), polarizing component, field stop, pupil stop, etc., known in the art of spectroscopic metrology. As depicted in FIG. 1, the illumination subsystem includes light source 110 and polarizing component 111. As depicted, in FIG. 1, the beam of illumination light 101 passes through polarizing component 111 as the beam propagates from the illumination source 110 to wafer 115. Beam 101 illuminates a portion of wafer 115 over a measurement site 116. In some embodiments, illumination light 101 is incident at wafer 115 at an angle of incidence, α, at or near 65 degrees from normal incidence.

In addition, the illumination subsystem may include filters, masks, beam shaping optics, illumination pupils, apodizers, etc. For example, the illumination subsystem may include an illumination field stop (not shown) and one or more optical filters (not shown). The illumination field stop controls the field of view (FOV) of the illumination subsystem and may include any suitable commercially available field stop. The optical filters are employed to control light level, spectral output, or both, from the illumination subsystem. In some examples, one or more multi-zone filters are employed as optical filters.

In some examples, noise and polarization optimization are performed to improve the performance of illumination source 110. In some examples, depolarization is achieved by use of multimode fibers, a Hanle depolarizer, or an integration sphere. In some examples, the illumination source etendue is optimized by use of light guides, fibers, and other optical elements (e.g., lenses, curved mirrors, apodizers, etc.). In some examples, source coherence or coherence effects are mitigated by coherence breaking techniques, or are otherwise accounted for by modeling and simulation.

Polarizing component 111 generates the desired polarization state exiting the illumination subsystem. In some embodiments, the polarizing component includes a polarizer, a compensator, or both, and may include any suitable commercially available polarizing component. The polarizer, compensator, or both, can be fixed, rotatable to different fixed positions, or continuously rotatable. Although the illumination subsystem depicted in FIG. 1 includes one polarizing component, the illumination subsystem may include more than one polarizing component. In some embodiments, a polarizer of polarizing component 111 is a Magnesium Fluoride Rochon polarizer. In some embodiments, a compensator of polarizing component 111 includes a quartz waveplate, a Magnesium Fluoride waveplate, a Calcium Fluoride K-prism, a Calcium Fluoride double Fresnel rhomb, or any combination thereof. In some embodiments, a compensator of polarizing component 111 includes one or more waveplates. In some of these embodiments, a first waveplate includes a desired retardation over a first wavelength range and a second waveplate includes a desired retardation over the first wavelength range a second, different wavelength range, etc.

As depicted in FIG. 1, illumination beam 101 is incident on wafer 115 at measurement site 116. Illumination beam 101 physically interacts with one or more structures under measurement at measurement site 116. The reflected beam 102 includes changes in wavefront phase and amplitude characteristics induced by the physical interaction.

As depicted in FIG. 1, beam 102 is reflected by reflective element 112 and is incident at site 113. In some embodiments site 113 is a portion of wafer 115 that includes another instance of the one or more structures under measurement at measurement site 116. In these embodiments, beam 102 physically interacts with the second instance of the one or more structures under measurement at site 113. The reflected beam 104 includes changes in wavefront phase and amplitude characteristics induced by the physical interaction.

As depicted in FIG. 1, beam 104 is reflected by reflective element 114 and is incident at measurement site 116 in a second pass. Beam 104 physically interacts with the instance of the one or more structures under measurement at measurement site 116. The reflected beam 106 includes changes in wavefront phase and amplitude characteristics induced by the physical interaction.

Metrology system 100 also includes a collection optics subsystem configured to collect light generated by the interaction between the one or more structures and the measurement beam and focus the collected light at or near a dispersive element, e.g., a spectrometer slit, of a spectrometer. The collection optics subsystem may include any type and arrangement of optical filter(s), polarizing component, field stop, pupil stop, etc., known in the art of spectroscopic metrology.

As depicted in FIG. 1, beam 106 passes through compensator 117 and analyzer 118 as beam 106 propagates from wafer 115 to dispersive element 119 of the spectrometer. As depicted in FIG. 1, the collection optics subsystem includes a polarizing component that analyzes the polarization state of the collected light. In some embodiments, the polarizing component includes an analyzer, a compensator, or both, and may include any suitable commercially available polarizing component. The analyzer, compensator, or both, can be fixed, rotatable to different fixed positions, or continuously rotatable. The collection subsystem depicted in FIG. 1 includes a compensator 117 and an analyzer 118. In general, a collection optics subsystem may include any number of polarizing elements.

In some embodiments, compensator 117 includes a quartz waveplate, a Magnesium Fluoride waveplate, a Calcium Fluoride K-prism, a Calcium Fluoride double Fresnel rhomb, or any combination thereof. In some embodiments, compensator 117 includes one or more waveplates. In some of these embodiments, a first waveplate includes a desired retardation over a first wavelength range and a second waveplate includes a desired retardation over the first wavelength range or a second, different wavelength range, etc. In some embodiments, analyzer 118 is a Magnesium Fluoride Rochon analyzer.

In the embodiment depicted in FIG. 1, a spectrometer subsystem includes dispersive element 119, and one or more optics having reflective focusing power (not shown). Dispersive element 119 is typically located at or near a pupil plane of the collection optics subsystem. Dispersive element 119 disperses the light into discrete wavelengths on the active surface of detector 120.

Dispersive element 119 is typically a diffraction grating or a dispersive prism. In some embodiments, dispersive element 119 includes one or more segments and each segment receives light from one or more corresponding apertures of a collection mask. In this manner, light dispersed by dispersive element 119 includes light corresponding to one or more discrete angles of incidence at the wafer. In some embodiments, dispersive element 119 is a planar diffraction grating. In some of these embodiments, the planar diffraction grating is segmented to split the pupil into segments each corresponding to a different set of discrete angles of incidence at the wafer. Further details regarding pupil splitting are described in U.S. Pat. No. 10,690,602 to KLA-Tencor Corporation, the content of which is incorporated herein by reference in its entirety.

As depicted in FIG. 1, detector 120 receives light collected from wafer 115 at one or more angles of incidence, multiple wavelengths, e.g., 140 nanometers to 2,500 nanometers, and one or more polarization states. In the embodiment depicted in FIG. 1, the collection optics subsystem directs light to detector 120 and the detector 120 generates output signals 122 responsive to light collected from the one or more structures under measurement. The dispersive element 119 linearly disperses diffracted light according to wavelength along one dimension of detector 120 (i.e., the wavelength dispersion direction noted in FIG. 1). Dispersive element 119 causes a spatial separation among different wavelengths of light projected onto the surface of detector 120. In this manner, light collected from measurement site 116 having a particular wavelength is projected onto detector 120 at a spatial location that is different from light collected from measurement site 116 having another, different wavelength.

Metrology system 100 also includes computing system 130 configured to receive detected signals 122 and determines an estimate 123 of a value of a parameter of interest of the measured structure(s) based on the detected signals.

In the aforementioned example, the measurement beam twice interacts with the first instance of the one or more structures under measurement at measurement site 116 in two passes, and once interacts with the second instance of the one or more structures under measurement in one pass. In this example, beam 106 includes wavefront phase and amplitude information associated with three interactions with the one or more structures under measurement.

In another embodiment, a reflective element coupled to metrology system 100 is located at site 113. In one embodiment, structural element 125 depicted in FIG. 1 is a reflective element separate from wafer 115, i.e., reflective element 125 is not a portion of wafer 115. Rather, reflective element 125 is directly or indirectly coupled to a frame that supports other optical elements of metrology system 100. In the embodiment depicted in FIG. 1, reflective element 125 is coupled to an actuator subsystem 105, e.g., a linear actuator. Actuator subsystem 105 is coupled to metrology system 100 and selectively moves reflective element 125 to site 113. In this embodiment, beam 102 is reflected by reflective element 112 and is incident on a reflective element present at site 113. In this embodiment, beam 102 simply reflects off the reflective element 125, and reflected beam 104 includes approximately the same wavefront phase and amplitude characteristics as beam 102.

In this example, the measurement beam twice interacts with the first instance of the one or more structures under measurement at measurement site 116 in two passes. In this example, beam 106 includes wavefront phase and amplitude information associated with two interactions with the one or more structures under measurement.

In the embodiment depicted in FIG. 1, reflective element 112 is coupled to an actuator subsystem 103, e.g., a linear actuator. Actuator subsystem 103 is coupled to metrology system 100 and selectively moves reflective element 112 in/out of the measurement beam path. In one configuration, actuator subsystem 103 moves reflective element 112 out of the measurement beam path. In this configuration, beam 102 passes through compensator 117 and analyzer 118 as beam 102 propagates from wafer 115 to dispersive element 119 of the spectrometer (depicted as a dashed line in FIG. 1).

In this example, the measurement beam interacts once with the first instance of the one or more structures under measurement at measurement site 116 in one pass. In this example, beam 102 includes wavefront phase and amplitude information associated with one interaction with the one or more structures under measurement as is the case in a conventional SE metrology subsystem. In some examples, single pass measurements may be convenient to perform for purposes of calibration, baseline validation, etc.

In the embodiment depicted in FIG. 1, metrology system 100 is easily configured to perform single pass, double pass, and triple pass measurements by simply controlling the position of reflective elements 112 and 125 in or out of the measurement beam path.

Although, metrology system 100 is optically configured in a two-pass configuration, in general, metrology system 100 may be optically configured in an N-pass configuration, where N is any positive, integer number greater than one. Although, metrology system 100 includes two reflective elements to direct light from measurement site 116 back to measurement site 116 in a second pass, in general, any suitable arrangement including any number of reflective optical elements to direct light from measurement site 116 back to measurement site 116 may be contemplated within the scope of this patent document.

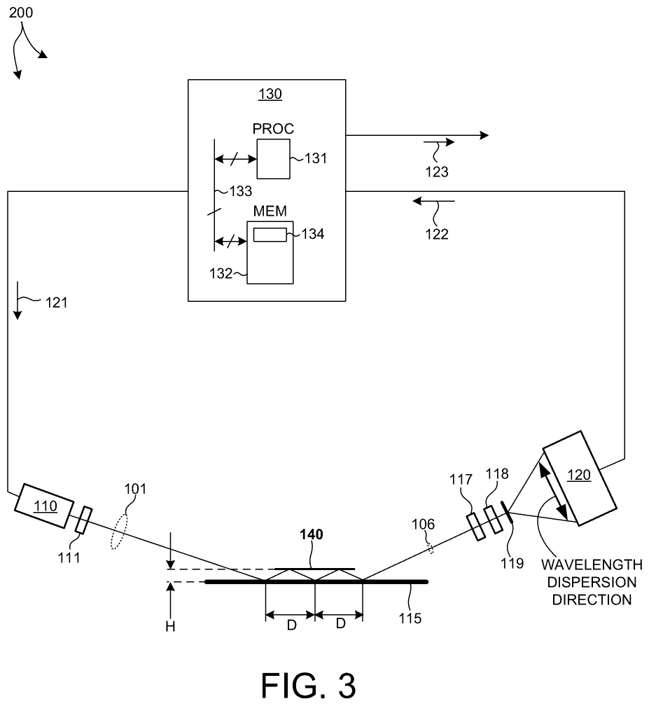

FIG. 3 depicts an exemplary, multiple pass metrology system 200 for performing broadband spectroscopic measurements of semiconductor structures (e.g., film thickness, critical dimensions, overlay, etc.). As depicted in FIG. 3, metrology system 200 is configured as an oblique incidence, broadband spectroscopic ellipsometer. However, in general, multiple pass metrology system 100 may also include additional spectroscopic ellipsometers, a spectroscopic reflectometer, scatterometer, or any combination thereof. Like numbered elements depicted in FIG. 3 are analogous to those described with reference to metrology system 100 described with reference to FIG. 1.

In the embodiment depicted in FIG. 3, a planar reflector 140 having a planar reflective surface is disposed over a portion of wafer 115 and facing the wafer surface. Planar reflector 140 is positioned in the optical path of the measurement beam and directs light from one measurement site to another measurement site on the surface of wafer 115. Each measurement site on wafer 115 includes a separate instance of one or more structures under measurement.

Planar reflector 140 is directly or indirectly coupled to a frame that supports other optical elements of metrology system 200. In some embodiments, planar reflector 140 is coupled to an actuator subsystem (not shown) that is coupled to metrology system 100. The actuator subsystem controls the position and orientation of planar reflector 140 relative to the surface of wafer 115 to ensure that the measurement beam is incident on more than one instance of one or more structures under measurement. For example, the planar reflector 140 should be positioned at a uniform height, H, above the surface of wafer 115 to ensure that the measurement beam is incident on wafer 115 at successive measurement sites separated by a distance, D. Distance, D, is known apriori as the distance between repeated instances of a structure under measurement, along with the angle of incidence of illumination beam 101. Based on the known angle of incidence, and distance, D, basic geometry is employed to calculate the desired separation distance, H.

In the embodiment depicted in FIG. 3, the measurement beam simply reflects off planar reflector 140 and with negligible change to the wavefront phase and amplitude characteristics as the measurement beam. However, at each incidence with wafer 115, the measurement beam interacts with an instance of the one or more structures under measurement. In this example, beam 106 includes wavefront phase and amplitude information associated with three interactions with the one or more structures under measurement.

In the embodiment depicted in FIG. 3, the measurement beam interacts with three instances of a structure under measurement. However, in general, planar reflective element 140 may be sized to accommodate two or more instances of a structure under measurement. In some embodiments, planar reflective element 140 is sized to accommodate up to ten instances of a structure under measurement.

In a further aspect, an optical modulation element is disposed in the optical path of the measurement system. In preferred embodiments, the optical modulation element is an optical element separate from the wafer and is not a portion of the semiconductor wafer. The physical interaction between the optical modulation element and the measurement beam changes the wavefront phase and amplitude properties of the measurement beam. The addition of an optical modulation element in the measurement beam path further enhances measurement sensitivity to critical parameters, e.g., CDs, shapes, and film thicknesses, and helps to break correlations between critical parameters that lead to undesirable measurement errors, excessive computational effort, or both. In some examples, measurement sensitivity may be amplified 6× to 25×, or more, by employing multiple pass measurements including optical modulation.

In preferred embodiments, one or more optical modulation targets are mounted to the measurement tool (not the wafer). Furthermore, the optical modulation targets are selectable for the measurement application at hand to amplify measurement sensitivity. The measurement signal response induced by each optical modulation target is calibrated periodically and the targets themselves are maintained in a controlled environment that minimizes drift over time. In general, any number of optical modulation targets may be loaded onto a measurement system. In some embodiments, a measurement tool includes a positioning system that selectively positions one or more optical modulation targets in the measurement beam path. In some embodiments, the positioning system moves an optical modulation targets from a storage position on board the measurement system to a position in the measurement path, and vice-versa. In some embodiments the positioning system, includes a carriage storing one or more optical modulation targets, and selectively moves each of the targets into the measurement path in accordance with a measurement recipe.

In some embodiments, optical modulation targets may be fabricated on a wafer under measurement. However, this approach is less desirable because the targets occupy valuable real estate on a wafer, cannot be as easily calibrated, are less likely to be mechanically and optically stable over time, cannot easily be adapted to new designs, etc. In addition, limiting the number of optical modulation targets to the number that can be accommodated within available area within the scribe lines of a wafer limits the process window that can be explored and potentially reduces the achievable yield.

In one embodiment, structural element 125 depicted in FIG. 1 is an optical modulation element separate from wafer 115, i.e., optical modulation element 125 is not a portion of wafer 115. In preferred embodiments, optical modulation element 125 is directly or indirectly coupled to a frame that supports other optical elements of metrology system 100. In the embodiment depicted in FIG. 1, optical modulation element 125 is coupled to an actuator subsystem 105, e.g., a modulator positioning subsystem. Actuator subsystem 105 is coupled to a structural element of metrology system 100 and selectively moves optical modulation element 125 in/out of the measurement beam path at site 113. In this embodiment, beam 102 is reflected by reflective element 112 and is incident on optical modulation element 125 present at site 113. In this embodiment, beam 102 physically interacts with one or more structures of optical modulation element 125 at site 113. The reflected beam 104 includes changes in wavefront phase and amplitude characteristics induced by the physical interaction.

In this example, the measurement beam twice interacts with the first instance of the one or more structures under measurement at measurement site 116 in two passes and interacts once with optical modulation element 125 in one pass. In this example, beam 106 includes wavefront phase and amplitude information associated with two interactions with the one or more structures under measurement and one interaction with optical modulation element 125.

In another embodiment, planar reflective element 140 depicted in FIG. 3 includes one or material layers that induce changes in wavefront phase and amplitude characteristics during physical interaction with the measurement beam. As such, in these embodiments, planar reflective element 140 is also an optical modulation element. In the embodiment depicted in FIG. 3, the measurement beam twice interacts with optical modulation element 140, in addition to three interactions with different instances of the primary target disposed on wafer 115. Thus, in this example, beam 106 includes wavefront phase and amplitude information associated with two interactions with optical modulation element 140 and three interactions with the primary target at three different measurement sites on wafer 115.

In the embodiment depicted in FIG. 1, the optical modulation element 125 is located at site 113 when inserted into the measurement beam path between the illumination source and the detector. In this configuration, the measurement beam interacts with the primary target at measurement site 116, the optical modulation target at site 113, and again with the primary target at measurement site 116. However, in general, any number of interactions with any number of instances of the primary target, any number of interactions with any number of the same or different optical modulation targets, and any order of interactions with primary and optical modulation targets, may be contemplated within the scope of this patent document.

In general, an optical modulation element is any structure that changes the wavefront phase and amplitude characteristics of the measurement beam. Exemplary optical modulation elements include, but are not limited to: a planar, bare crystalline silicon substrate, a layer of silicon dioxide deposited over a bare crystalline silicon substrate, a patterned structure fabricated on a layer of silicon dioxide deposited over a bare crystalline silicon substrate, a mirror, a filter, an optical amplifier, an optical bandgap filter, a waveguide, a diffraction grating, a dielectric Bragg reflector, etc.

In some embodiments, the optical modulator element is tunable, e.g., by changing the orientation or position of the optical modulator element with respect to the measurement beam, by applying a voltage to the optical modulator element, etc. For example, thin-film interference filters, tunable, Fabry-Perrot filters, MEMS-based Fabry-Perot filters, waveguides, diffraction gratings, dielectric Bragg reflectors (DBR) are positional optical components that enable modulation of measurement target sensitivity.

In some embodiments, the optical modulator includes a silicon based filter or mirror that passes light within a specific spectral range, e.g., UV to IR, designed to meet requirements for SCD or film measurements.

In general, an optical modulation element is designed to achieve a desired optical functionality and structural stability. For example, optical modulation elements fabricated with silicon, amorphous silicon, silicon dioxide, silicon nitride, etc., offer good optical performance and are mechanically and optically stable. Beyond material selection, the optical properties of an optical modulation element may be tuned by adjusting the thickness of layers of the filter stack, controlling the position and orientation of the optical modulation element with respect to the measurement beam, controlling a voltage applied to the optical modulation element, etc.

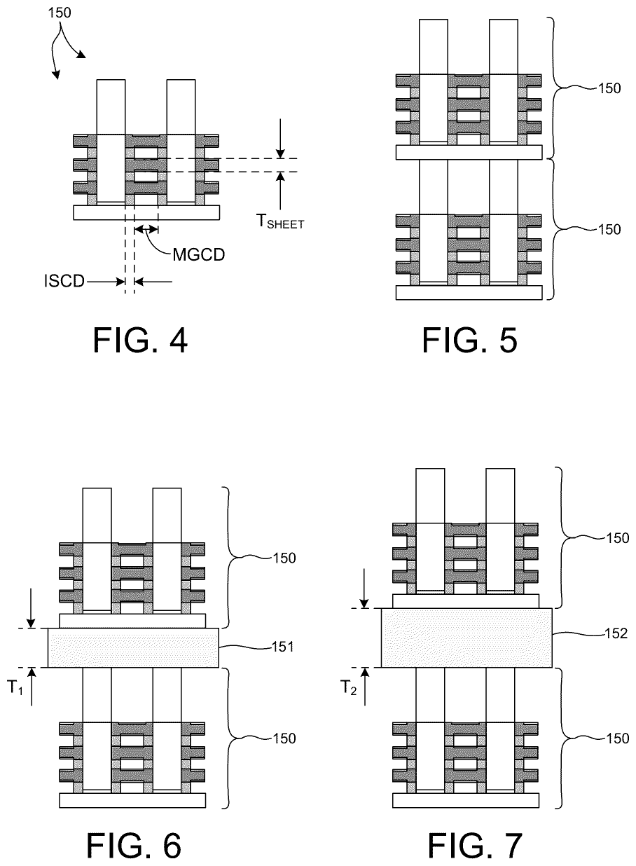

FIG. 4 is a simplified diagram illustrative of a nanosheet based semiconductor structure 150 in one embodiment. FIG. 4 depicts the nanosheet based semiconductor structure 150 after the Silicon Germanium (SiGe) release step. Several geometric parameters are critical after the SiGe release step. Exemplary critical parameters include the metal gate critical dimensions associated with each nanosheet, e.g., MGCD, the thickness associated with each nanosheet, e.g., T_{SHEET}, the shape profile of the inner spacers, e.g., ISCD, etc. Independent measurement of these dimensions and shape profiles is very challenging given the complexity of the structures and the relatively low volume of the critical dimensions and features.

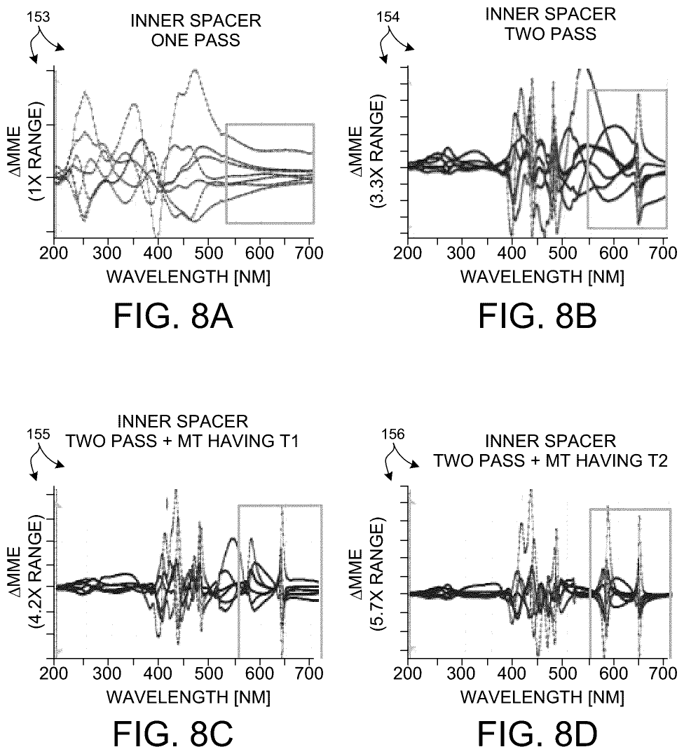

FIGS. 8A-8D are plots illustrative of a simulation of the sensitivity of a number of different Mueller Matrix elements to a change in dimension of ISCD by one nanometer for a number of different measurement scenarios. As depicted in FIGS. 8A-8D, each plotline is associated with a different Mueller Matrix element.

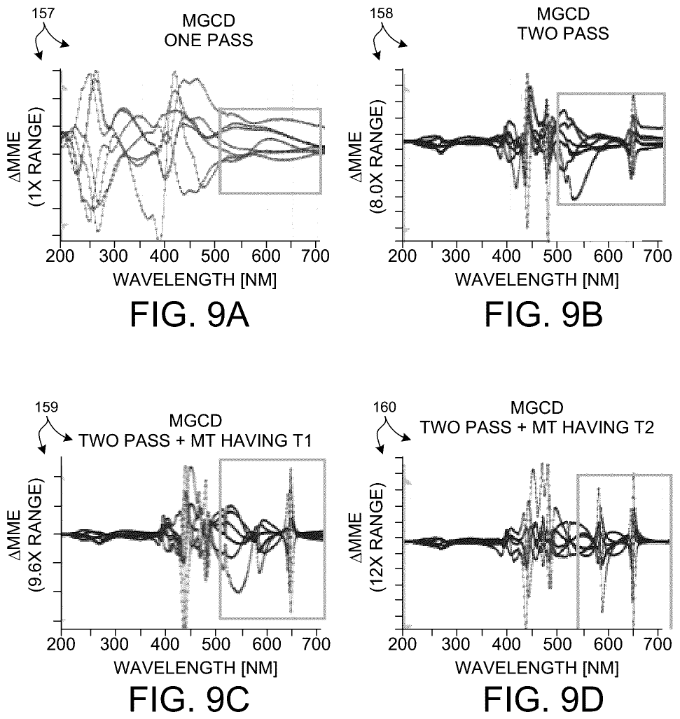

FIGS. 9A-9D are plots illustrative of a simulation of the sensitivity of a number of different Mueller Matrix elements to a change in dimension of MGCD by one nanometer for each of the different measurement scenarios associated with FIGS. 8A-8D, respectively. As depicted in FIGS. 9A-9D, each plotline is associated with a different Mueller Matrix element.

FIG. 8A is a plot 153 illustrative of the difference in simulated spectral values associated with each of a number of Mueller Matrix elements induced by a change in dimension of ISCD by one nanometer for a conventional, single pass SE measurement, e.g., a single pass SE measurement as described with reference to FIG. 1. As depicted in FIG. 8A, the scale of the y-axis is 1×.

Similarly, FIG. 9A is a plot 157 illustrative of the difference in simulated spectral values associated with each of a number of Mueller Matrix elements induced by a change in dimension of MGCD by one nanometer for a conventional, single pass SE measurement. As depicted in FIG. 9A, the scale of the y-axis is 1×.

In some embodiments, a two pass measurement is performed without an optical modulation element in the optical beam path as described with respect to FIGS. 1 and 3. FIG. 5 is a simplified diagram illustrative of two instances of nanosheet based semiconductor structure 150. FIG. 5 visually illustrates the stack up of two instances of nanosheet based semiconductor structure 150 as encountered by a multiple pass measurement beam directed to interrogate two instances of nanosheet based semiconductor structure 150.

FIG. 8B is a plot 154 illustrative of the difference in simulated spectral values associated with each of a number of Mueller Matrix elements induced by a change in dimension of ISCD by one nanometer for a two-pass SE measurement, e.g., a two-pass SE measurement as described with reference to FIG. 1. As depicted in FIG. 8B, the scale of the y-axis is 3.3×. In other words, the variation in amplitude of signals plotted in FIG. 8B would appear 3.3× larger along the y-axis if plotted with the same scale as FIG. 8A. As illustrated in FIG. 8B, the simulated spectral values associated with each of a number of Mueller Matrix elements are amplified by 2-3×, or more, compared to the corresponding values associated with a single pass measurement depicted in FIG. 8A.

FIG. 9B is a plot 158 illustrative of the difference in simulated spectral values associated with each of a number of Mueller Matrix elements induced by a change in dimension of MGCD by one nanometer for a two-pass SE measurement. As depicted in FIG. 9B, the scale of the y-axis is 8.0×. In other words, the variation in amplitude of signals plotted in FIG. 9B would appear 8.0× larger along the y-axis if plotted with the same scale as FIG. 9A. As illustrated in FIG. 9B, the simulated spectral values associated with each of a number of Mueller Matrix elements are amplified by 5-8×, or more, compared to the corresponding values associated with a single pass measurement depicted in FIG. 9A.

In some embodiments, a two pass measurement is performed with an optical modulation element in the optical beam path as described with respect to FIGS. 1 and 3. FIG. 6 is a simplified diagram illustrative of two instances of nanosheet based semiconductor structure 150 separated by a layer of silicon dioxide 151 having a thickness of 50 nanometers. FIG. 6 visually illustrates the stack up of one instance of nanosheet based semiconductor structure 150, an instance of an optical modulation target, and another instance of nanosheet based semiconductor structure 150 as encountered by a multiple pass measurement beam directed to interrogate two instances of nanosheet based semiconductor structure 150 and an instance of an optical modulation target.

FIG. 8C is a plot 155 illustrative of the difference in simulated spectral values associated with each of a number of Mueller Matrix elements induced by a change in dimension of ISCD by one nanometer for an SE measurement than includes two-passes of the primary target and one pass of the optical modulation target, e.g., as described with reference to FIG. 1. As depicted in FIG. 8C, the scale of the y-axis is 4.2×. In other words, the variation in amplitude of signals plotted in FIG. 8C would appear 4.2× larger along the y-axis if plotted with the same scale as FIG. 8A. As illustrated in FIG. 8C, the simulated spectral values associated with each of a number of Mueller Matrix elements are amplified even more significantly than FIG. 8B.

FIG. 9C is a plot 159 illustrative of the difference in simulated spectral values associated with each of a number of Mueller Matrix elements induced by a change in dimension of MGCD by one nanometer for an SE measurement than includes two-passes of the primary target and one pass of the optical modulation target. As depicted in FIG. 9C, the scale of the y-axis is 9.6×. In other words, the variation in amplitude of signals plotted in FIG. 9C would appear 9.6× larger along the y-axis if plotted with the same scale as FIG. 9A. As illustrated in FIG. 9C, the simulated spectral values associated with each of a number of Mueller Matrix elements are amplified even more significantly than FIG. 9B.

FIG. 7 is a simplified diagram illustrative of two instances of nanosheet based semiconductor structure 150 separated by a layer of silicon dioxide 151 having a thickness of 100 nanometers. FIG. 7 visually illustrates the stack up of one instance of nanosheet based semiconductor structure 150, an instance of an optical modulation target, and another instance of nanosheet based semiconductor structure 150 as encountered by a multiple pass measurement beam directed to interrogate two instances of nanosheet based semiconductor structure 150 and an instance of an optical modulation target.

FIG. 8D is a plot 156 illustrative of the difference in simulated spectral values associated with each of a number of Mueller Matrix elements induced by a change in dimension of ISCD by one nanometer for an SE measurement than includes two-passes of the primary target and one pass of the optical modulation target. As depicted in FIG. 8D, the scale of the y-axis is 5.7×. In other words, the variation in amplitude of signals plotted in FIG. 8D would appear 5.7× larger along the y-axis if plotted with the same scale as FIG. 8A. As illustrated in FIG. 8D, the simulated spectral values associated with each of a number of Mueller Matrix elements are amplified even more significantly than FIG. 8B.

FIG. 9D is a plot 160 illustrative of the difference in simulated spectral values associated with each of a number of Mueller Matrix elements induced by a change in dimension of MGCD by one nanometer for an SE measurement than includes two-passes of the primary target and one pass of the optical modulation target. As depicted in FIG. 9D, the scale of the y-axis is 12.0×. In other words, the variation in amplitude of signals plotted in FIG. 9D would appear 12.0× larger along the y-axis if plotted with the same scale as FIG. 9A. As illustrated in FIG. 9D, the simulated spectral values associated with each of a number of Mueller Matrix elements are amplified even more significantly than FIG. 9B.

Measurement signal amplification is particularly pronounced in the spectral range from 550 nanometers to 700 nanometers. This spectral region is highlighted by a box that appears in each of FIGS. 8A-8D and FIGS. 9A-9D.

In another aspect, an optical modulation target is combined with multiple pass measurements to amplify measurement sensitivity to thickness and composition. In some embodiments, the primary target includes at least one layer of a material with a specified thickness, and the optical modulation element also includes the at least one layer of the material with the specified thickness, or a different thickness. In some of these embodiments, the optical modulation element includes the at least one layer of the material with a specified thickness that is an integer multiple of the corresponding specified thickness of the material in the primary target.

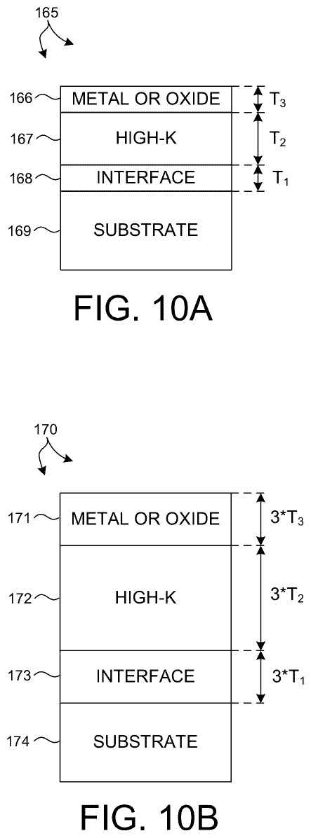

In some embodiments, a film thickness target includes multiple layers of different materials. For example, FIG. 10A is a simplified diagram illustrative of a thin film structure under measurement, i.e., a primary target. As depicted in FIG. 10A, the primary film thickness target 165 includes a substrate 169, e.g., Silicon, an interface layer 168, e.g., Silicon dioxide, having a thickness, T₁, a high-K dielectric layer 167, e.g., Hafnium oxide, having a thickness, T₂, and a metal or oxide layer 166, e.g., Titanium nitride, Lanthanum oxide, Aluminum oxide, etc., having a thickness, T₃.

FIG. 10B is a simplified diagram illustrative of an optical modulation target 170 employed as part of a multiple pass measurement, along with primary target 165 depicted in FIG. 10A. As depicted in FIG. 10B, optical modulation target 170 is similar to primary target 165, except the thickness of the interface layer, high-K layer, and metal or oxide layer are each three times that of the corresponding layers of primary target 165. As depicted in FIG. 10B, the optical modulation target 170 includes a substrate 174, e.g., Silicon, an interface layer 173, e.g., Silicon dioxide, having a thickness, 3*T₁, a high-K dielectric layer 172, e.g., Hafnium oxide, having a thickness, 3*T₂, and a metal or oxide layer 171, e.g., Titanium nitride, Lanthanum oxide, Aluminum oxide, etc., having a thickness, 3*T₃.

In one embodiment, a two pass SE measurement of primary target 165 that includes an optical pass of optical modulation target 170 is simulated where the thickness of a silicon dioxide interface layer 169 is 10 Angstroms, the thickness of a hafnium oxide High-K layer 167 is 18 Angstroms and the thickness of a titanium nitride metal layer 166 is 10 Angstroms. Similarly, the thickness of a silicon dioxide interface layer 173 is 30 Angstroms, the thickness of a hafnium oxide High-K layer 172 is 54 Angstroms and the thickness of a Titanium nitride metal layer 171 is 30 Angstroms

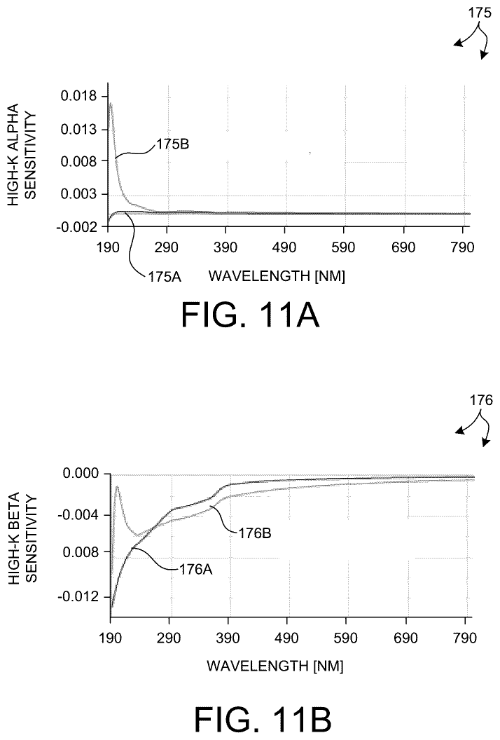

FIG. 11A is a plot 175 illustrative of the difference in simulated spectral values associated with the alpha harmonic signal induced by a change in thickness of the hafnium oxide High-K layer 167 by one Angstrom for two measurement scenarios. Plotline 175A illustrates a conventional single pass SE measurement of the primary target 165. Plotline 175B illustrates an SE measurement than includes two-passes of the primary target 165 and one pass of the optical modulation target 170. As illustrated in FIG. 11A, the sensitivity of the alpha harmonic signal to a change of value of the thickness of hafnium oxide layer 167 for a multiple pass measurement including an optical modulation element is approximately 20× greater than the corresponding sensitivity for a single pass measurement.

FIG. 11B is a plot 176 illustrative of the difference in simulated spectral values associated with the beta harmonic signal induced by a change in thickness of the hafnium oxide High-K layer 167 by one Angstrom for two measurement scenarios. Plotline 176A illustrates a conventional single pass SE measurement of the primary target 165. Plotline 176B illustrates an SE measurement than includes two-passes of the primary target 165 and one pass of the optical modulation target 170. As illustrated in FIG. 11B, the sensitivity of the beta harmonic signal to a change of value of the thickness of hafnium oxide layer 167 for a multiple pass measurement including an optical modulation element is comparable to the corresponding sensitivity for a single pass measurement.

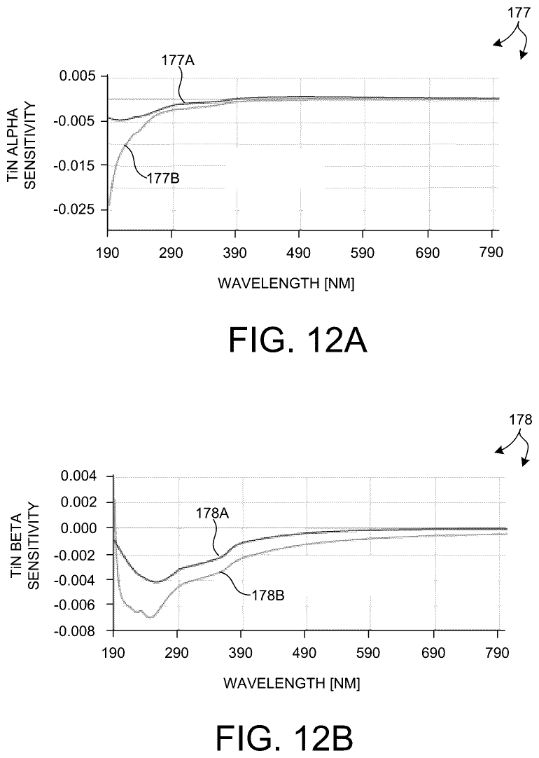

FIG. 12A is a plot 177 illustrative of the difference in simulated spectral values associated with the alpha harmonic signal induced by a change in thickness of the tin oxide layer 166 by one Angstrom for two measurement scenarios. Plotline 177A illustrates a conventional single pass SE measurement of the primary target 165. Plotline 177B illustrates an SE measurement than includes two-passes of the primary target 165 and one pass of the optical modulation target 170. As illustrated in FIG. 12A, the sensitivity of the alpha harmonic signal to a change of value of the thickness of tin oxide layer 166 for a multiple pass measurement including an optical modulation element is approximately 5× greater than the corresponding sensitivity for a single pass measurement.

FIG. 12B is a plot 178 illustrative of the difference in simulated spectral values associated with the beta harmonic signal induced by a change in thickness of the titanium nitride layer 166 by one Angstrom for two measurement scenarios. Plotline 178A illustrates a conventional single pass SE measurement of the primary target 165. Plotline 178B illustrates an SE measurement than includes two-passes of the primary target 165 and one pass of the optical modulation target 170. As illustrated in FIG. 12B, the sensitivity of the beta harmonic signal to a change of value of the thickness of titanium nitride layer 166 for a multiple pass measurement including an optical modulation element is approximately 1.7× greater than the corresponding sensitivity for a single pass measurement.

In a further aspect, multiple pass measurements using different combinations of optical modulation targets are combined in a multi-target measurement to further enhance measurement sensitivity and break correlations.

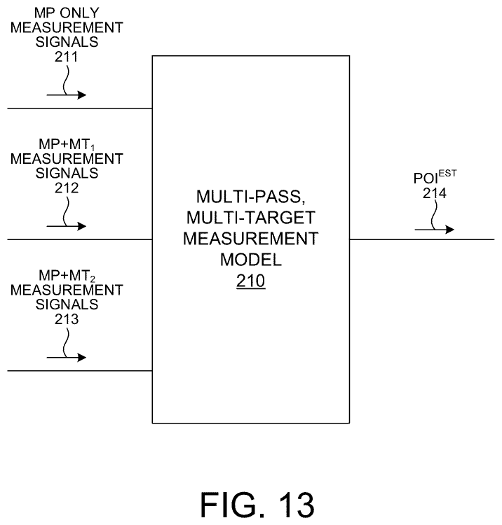

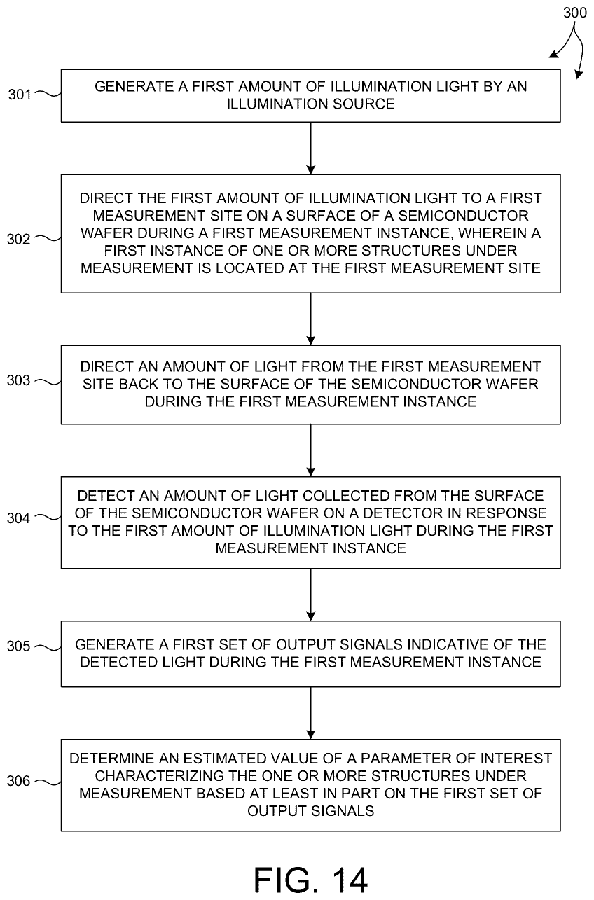

FIG. 13 is a diagram illustrative of a multi-pass, multi-target measurement model 210 in one embodiment. As depicted in FIG. 13, multi-pass, multi-target measurement model 210 receives measurement signals, e.g., spectral measurement signals 122 illustrated in FIG. 1, associated with several multiple pass measurement scenarios. More specifically, multi-pass, multi-target measurement model 210 receives measurement signals 211 associated with a multiple pass measurement of a primary target without an optical modulation element in the measurement path, measurement signals 212 associated with a multiple pass measurement of the primary target with an optical modulation element in a first configuration (MT₁) in the measurement path, and measurement signals 213 associated with a multiple pass measurement of the primary target with an optical modulation element in a second configuration (MT₂) in the measurement path.

In one example, measurement signals 211 are associated with a two pass measurement of primary target 150 depicted in FIG. 5, measurement signals 212 are associated with a two pass measurement of primary target 150 including optical modulation element 151 having a thickness of 50 nanometers depicted in FIG. 6, and measurement signals 213 are associated with a two pass measurement of primary target 150 including optical modulation element 152 having a thickness of 100 nanometers depicted in FIG. 7. The multi-pass, multi-target measurement model 210 receives measurement signals 211, 212, and 213, and estimates the values of one or more parameters of interest, POI_{EST} 214, based on the received measurement signals. In one example, the parameter of interest is the inner spacer critical dimension (ISCD) of GAA structure 150 depicted in FIG. 4. In another example, the parameter of interest is the metal gate critical dimension (MGCD) of GAA structure 150 depicted in FIG. 4. In another example, the parameter of interest is the sheet thickness (T_{SHEET}) Of GAA structure 150 depicted in FIG. 4.

In some examples, the use of a silicon dioxide film on a silicon substrate as an optical modulator as depicted in FIGS. 6 and 7 as part of a multiple pass, multiple target measurement amplifies the measurement sensitivity of an SE measurement of critical parameters of a GAA structure, such as GAA structure 150 depicted in FIG. 4, by 4-10×.

Although FIG. 13 depicts a multi-pass, multi-target measurement model having signal inputs associated with three different measurement scenarios, any multi-pass, multi-target measurement model having two or more measurement signal inputs, each associated with a different measurement scenario, is contemplated within this patent document.

In some embodiments, a multi-pass, multi-target measurement model estimates values of one or more parameters of interest based on measurement signals associated with a multiple pass measurement of a primary target without an optical modulation target and measurement signals associated with multiple pass measurements of the primary target with an optical modulation target in any number of configurations.

In some embodiments, a multi-pass, multi-target measurement model estimates values of one or more parameters of interest based on measurement signals associated with multiple pass measurements of a primary target with one or more optical modulation targets in any number of different configurations.

In some embodiments, the methods and systems for spectroscopic metrology of semiconductor devices described herein are applied to the measurement of high aspect ratio (HAR), large lateral dimension structures, opaque film layers, or a combination thereof. These embodiments enable optical critical dimension (CD), film, and composition metrology for semiconductor devices with HAR structures (e.g., NAND, VNAND, TCAT, DRAM, etc.) and, more generally, for complex devices that suffer from low light penetration into the structure(s) being measured. HAR structures often include hard mask layers to facilitate etch processes for HARs. As described herein, the term “HAR structure” refers to any structure characterized by an aspect ratio that exceeds 2:1 or 10:1, and may be as high as 100:1, or higher.

In the embodiment depicted in FIG. 1, computing system 130 is configured to receive signals 122 indicative of the spectral response detected by the detector subsystem. Computing system 130 is further configured to determine control signals 121 that are communicated to programmable illumination source 110. Programmable illumination source 110 receives control signals 121 and adjusts the light output from illumination source 110 to achieve the desired illumination.

FIG. 8 illustrates a method 300 of performing spectroscopic measurements in at least one novel aspect. Method 300 is suitable for implementation by a metrology system such as metrology system 100 illustrated in FIG. 1 of the present invention. In one aspect, it is recognized that data processing blocks of method 300 may be carried out via a pre-programmed algorithm executed by one or more processors of computing system 130, or any other general purpose computing system. It is recognized herein that the particular structural aspects of metrology system 100 do not represent limitations and should be interpreted as illustrative only.

In block 301, a first amount of illumination light is generated by an illumination source.

In block 302, the first amount of illumination light is directed to a first measurement site on a surface of a semiconductor wafer during a first measurement instance. A first instance of one or more structures under measurement is located at the first measurement site.

In block 303, an amount of light is directed from the first measurement site back to the surface of the semiconductor wafer during the first measurement instance.

In block 304, an amount of light collected from the surface of the semiconductor wafer is detected on a detector in response to the first amount of illumination light during the first measurement instance.

In block 305, a first set of output signals indicative of the detected light during the first measurement instance is generated.

In block 306, an estimated value of a parameter of interest characterizing the one or more structures under measurement is determined based at least in part on the first set of output signals.

In a further embodiment, system 100 includes one or more computing systems 130 employed to perform measurements of actual device structures based on spectroscopic measurement data collected in accordance with the methods described herein. The one or more computing systems 130 may be communicatively coupled to the spectrometer. In one aspect, the one or more computing systems 130 are configured to receive measurement data associated with measurements of the structure of the specimen under measurement.

It should be recognized that one or more steps described throughout the present disclosure may be carried out by a single computer system 130 or, alternatively, a multiple computer system 130. Moreover, different subsystems of system 100 may include a computer system suitable for carrying out at least a portion of the steps described herein. Therefore, the aforementioned description should not be interpreted as a limitation on the present invention but merely an illustration.

In addition, the computer system 130 may be communicatively coupled to the spectrometers in any manner known in the art. For example, the one or more computing systems 130 may be coupled to computing systems associated with the spectrometers. In another example, the spectrometers may be controlled directly by a single computer system coupled to computer system 130.

The computer system 130 of metrology system 100 may be configured to receive and/or acquire data or information from the subsystems of the system (e.g., spectrometers and the like) by a transmission medium that may include wireline and/or wireless portions. In this manner, the transmission medium may serve as a data link between the computer system 130 and other subsystems of system 100.

Computer system 130 of metrology system 100 may be configured to receive and/or acquire data or information (e.g., measurement results, modeling inputs, modeling results, reference measurement results, etc.) from other systems by a transmission medium that may include wireline and/or wireless portions. In this manner, the transmission medium may serve as a data link between the computer system 130 and other systems (e.g., memory on-board metrology system 100, external memory, or other external systems). For example, the computing system 130 may be configured to receive measurement data from a storage medium (i.e., memory 132 or an external memory) via a data link. For instance, spectral results obtained using the spectrometers described herein may be stored in a permanent or semi-permanent memory device (e.g., memory 132 or an external memory). In this regard, the spectral results may be imported from on-board memory or from an external memory system. Moreover, the computer system 130 may send data to other systems via a transmission medium. For instance, a measurement model or an estimated parameter value 171 determined by computer system 130 may be communicated and stored in an external memory. In this regard, measurement results may be exported to another system.

Computing system 130 may include, but is not limited to, a personal computer system, mainframe computer system, workstation, image computer, parallel processor, or any other device known in the art. In general, the term “computing system” may be broadly defined to encompass any device having one or more processors, which execute instructions from a memory medium.

Program instructions 134 implementing methods such as those described herein may be transmitted over a transmission medium such as a wire, cable, or wireless transmission link. For example, as illustrated in FIG. 1, program instructions 134 stored in memory 132 are transmitted to processor 131 over bus 133. Program instructions 134 are stored in a computer readable medium (e.g., memory 132). Exemplary computer-readable media include read-only memory, a random access memory, a magnetic or optical disk, or a magnetic tape.

In some examples, the measurement models are implemented as an element of a SpectraShape® optical critical-dimension metrology system available from KLA-Tencor Corporation, Milpitas, California, USA. In this manner, the model is created and ready for use immediately after the spectra are collected by the system.

In some other examples, the measurement models are implemented off-line, for example, by a computing system implementing AcuShape® software available from KLA-Tencor Corporation, Milpitas, California, USA. The resulting, trained model may be incorporated as an element of an AcuShape® library that is accessible by a metrology system performing measurements.

In another aspect, the methods and systems for spectroscopic metrology of semiconductor devices described herein are applied to the measurement of high aspect ratio (HAR) structures, large lateral dimension structures, or both. The described embodiments enable optical critical dimension (CD), film, and composition metrology for semiconductor devices including three dimensional NAND structures, such as vertical-NAND (V-NAND) structures, dynamic random access memory structures (DRAM), etc., manufactured by various semiconductor manufacturers such as Samsung Inc. (South Korea), SK Hynix Inc. (South Korea), Toshiba Corporation (Japan), and Micron Technology, Inc. (United States), etc. These complex devices suffer from low light penetration into the structure(s) being measured. FIG. 3 depicts an exemplary high aspect ratio structure 160 that suffers from low light penetration into the structure(s) being measured. A spectroscopic ellipsometer with broadband capability and wide ranges of AOI, azimuth angle, or both, having simultaneous spectral band detection as described herein is suitable for measurements of these high-aspect ratio structures. HAR structures often include hard mask layers to facilitate etch processes for HARs. As described herein, the term “HAR structure” refers to any structure characterized by an aspect ratio that exceeds 2:1 or 10:1, and may be as high as 100:1, or higher.

In yet another aspect, the measurement results described herein can be used to provide active feedback to a process tool (e.g., lithography tool, etch tool, deposition tool, etc.). For example, values of measured parameters determined based on measurement methods described herein can be communicated to a lithography tool to adjust the lithography system to achieve a desired output. In a similar way etch parameters (e.g., etch time, diffusivity, etc.) or deposition parameters (e.g., time, concentration, etc.) may be included in a measurement model to provide active feedback to etch tools or deposition tools, respectively. In some example, corrections to process parameters determined based on measured device parameter values and a trained measurement model may be communicated to a lithography tool, etch tool, or deposition tool.

As described herein, the term “critical dimension” includes any critical dimension of a structure (e.g., bottom critical dimension, middle critical dimension, top critical dimension, sidewall angle, grating height, etc.), a critical dimension between any two or more structures (e.g., distance between two structures), and a displacement between two or more structures (e.g., overlay displacement between overlaying grating structures, etc.). Structures may include three dimensional structures, patterned structures, overlay structures, etc.

As described herein, the term “critical dimension application” or “critical dimension measurement application” includes any critical dimension measurement.

As described herein, the term “metrology system” includes any system employed at least in part to characterize a specimen in any aspect, including measurement applications such as critical dimension metrology, overlay metrology, focus/dosage metrology, and composition metrology. However, such terms of art do not limit the scope of the term “metrology system” as described herein. In addition, the metrology system 100 may be configured for measurement of patterned wafers and/or unpatterned wafers. The metrology system may be configured as a LED inspection tool, edge inspection tool, backside inspection tool, macro-inspection tool, or multi-mode inspection tool (involving data from one or more platforms simultaneously), and any other metrology or inspection tool that benefits from the calibration of system parameters based on critical dimension data.

Various embodiments are described herein for a semiconductor measurement system that may be used for measuring a specimen within any semiconductor processing tool (e.g., an inspection system or a lithography system). The term “specimen” is used herein to refer to a wafer, a reticle, or any other sample that may be processed (e.g., printed or inspected for defects) by means known in the art.

As used herein, the term “wafer” generally refers to substrates formed of a semiconductor or non-semiconductor material. Examples include, but are not limited to, monocrystalline silicon, gallium arsenide, and indium phosphide. Such substrates may be commonly found and/or processed in semiconductor fabrication facilities. In some cases, a wafer may include only the substrate (i.e., bare wafer). Alternatively, a wafer may include one or more layers of different materials formed upon a substrate. One or more layers formed on a wafer may be “patterned” or “unpatterned.” For example, a wafer may include a plurality of dies having repeatable pattern features.

A “reticle” may be a reticle at any stage of a reticle fabrication process, or a completed reticle that may or may not be released for use in a semiconductor fabrication facility. A reticle, or a “mask,” is generally defined as a substantially transparent substrate having substantially opaque regions formed thereon and configured in a pattern. The substrate may include, for example, a glass material such as amorphous SiO2. A reticle may be disposed above a resist-covered wafer during an exposure step of a lithography process such that the pattern on the reticle may be transferred to the resist.

One or more layers formed on a wafer may be patterned or unpatterned. For example, a wafer may include a plurality of dies, each having repeatable pattern features. Formation and processing of such layers of material may ultimately result in completed devices. Many different types of devices may be formed on a wafer, and the term wafer as used herein is intended to encompass a wafer on which any type of device known in the art is being fabricated.

In one or more exemplary embodiments, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a general purpose or special purpose computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

Although certain specific embodiments are described above for instructional purposes, the teachings of this patent document have general applicability and are not limited to the specific embodiments described above. Accordingly, various modifications, adaptations, and combinations of various features of the described embodiments can be practiced without departing from the scope of the invention as set forth in the claims.

What is claimed is:

1. A measurement system comprising:
an illumination source configured to generate a first amount of illumination light directed to a first measurement site on a surface of a semiconductor wafer during a first measurement instance, wherein a first instance of one or more structures under measurement is located at the first measurement site;
at least one detector having a planar, two-dimensional surface sensitive to incident light, the at least one detector configured to detect an amount of light collected from the surface of the semiconductor wafer in response to the first amount of illumination light and generate a first set of output signals indicative of the detected light during the first measurement instance;
one or more reflective optical elements disposed in an optical path between the illumination source and the at least one detector, wherein the optical path is incident on the surface of the semiconductor wafer more than once; and
a computing system configured to determine an estimated value of a parameter of interest characterizing the one or more structures under measurement based at least in part on the first set of output signals.

2. The measurement system of claim 1, the one or more reflective optical elements including at least two reflective optical elements, the at least two reflective optical elements positioned in the optical path to direct light from the first measurement site back to the first measurement site.

3. The measurement system of claim 1, the one or more reflective optical elements including a planar reflector having a planar reflective surface disposed over the wafer and facing the wafer surface, wherein the planar reflector is positioned in the optical path to direct light from the first measurement site to a second measurement site on the surface of the semiconductor wafer, wherein a second instance of the one or more structures under measurement is located at the second measurement site.

4. The measurement system of claim 1, further comprising:
an optical modulation element disposed in the optical path, wherein the optical modulation element is not a portion of the semiconductor wafer.

5. The measurement system of claim 4, further comprising:
a modulator positioning subsystem mechanically fixed to a structural element of the measurement system, wherein the modulator positioning subsystem selectively positions the optical modulation element in and out of the optical path.

6. The measurement system of claim 4, wherein the one or more structures under measurement include at least one layer of a first material having a first thickness, and wherein the optical modulation element includes at least one layer of the first material having the first thickness or a second thickness different from the first thickness.

7. The measurement system of claim 6, wherein the second thickness is an integer multiple of the first thickness.

8. The measurement system of claim 4, wherein the optical modulation element is any of a planar, bare crystalline silicon substrate, a layer of silicon dioxide deposited over a bare crystalline silicon substrate, and a patterned structure fabricated on a layer of silicon dioxide deposited over a bare crystalline silicon substrate.

9. The measurement system of claim 1, the illumination source further configured to generate a second amount of illumination light directed to the first measurement site on the surface of the semiconductor wafer during a second measurement instance, the at least one detector further configured to detect an amount of light collected from the surface of the semiconductor wafer in response to the second amount of illumination light and generate a second set of output signals indicative of the detected light during the second measurement instance, wherein the computing system determines the estimated value of the parameter of interest characterizing the one or more structures under measurement based at least in part on the first and second sets of output signals.

10. The measurement system of claim 9, wherein an optical modulation element is disposed in the optical path during the first measurement instance and the optical modulation element is not disposed in the optical path during the second measurement instance.

11. The measurement system of claim 9, wherein a first optical modulation element is disposed in the optical path during the first measurement instance and a second optical modulation element is disposed in the optical path during the second measurement instance, wherein the first optical modulation element is different from the second optical modulation element.

12. The measurement system of claim 1, wherein the illumination source is a broadband illumination light source.

13. The measurement system of claim 1, wherein the illumination source, detector, one or more reflective elements comprise a spectroscopic ellipsometer, a spectroscopic reflectometer, or a single wavelength ellipsometer.

14. The measurement system of claim 1, wherein the one or more structures under measurement includes a critical dimension structure or a thin film structure.

15. A method comprising:
generating a first amount of illumination light by an illumination source;
directing the first amount of illumination light to a first measurement site on a surface of a semiconductor wafer during a first measurement instance, wherein a first instance of one or more structures under measurement is located at the first measurement site;
directing an amount of light from the first measurement site back to the surface of the semiconductor wafer during the first measurement instance;
detecting an amount of light collected from the surface of the semiconductor wafer on a detector in response to the first amount of illumination light during the first measurement instance;
generating a first set of output signals indicative of the detected light during the first measurement instance; and
determining an estimated value of a parameter of interest characterizing the one or more structures under measurement based at least in part on the first set of output signals.

16. The method of claim 15, wherein the amount of light directed from the first measurement site back to the surface of the semiconductor wafer during the first measurement instance is incident to the surface of the semiconductor wafer at the first measurement site.

17. The method of claim 15, wherein the amount of light directed from the first measurement site back to the surface of the semiconductor wafer during the first measurement instance is incident to the surface of the semiconductor wafer at a second measurement site, wherein a second instance of the one or more structures under measurement is located at the second measurement site.

18. The method of claim 15, further comprising:
optically modulating an amount of light in an optical path from the illumination source to the detector during the first measurement instance, wherein the optical modulation is performed by an optical modulation element that is not a portion of the semiconductor wafer.

19. The method of claim 18, wherein the one or more structures under measurement include at least one layer of a first material having a first thickness, and wherein the optical modulation element includes at least one layer of the first material having the first thickness or a second thickness different from the first thickness.

20. The method of claim 15, further comprising:
generating a second amount of illumination light;
directing the second amount of illumination light to the first measurement site on the surface of the semiconductor wafer during a second measurement instance;
detecting an amount of light collected from the surface of the semiconductor wafer in response to the second amount of illumination light;
generating a second set of output signals indicative of the detected light during the second measurement instance;
determining the estimated value of the parameter of interest characterizing the one or more structures under measurement based at least in part on the first and second sets of output signals.

21. The method of claim 20, further comprising:
optically modulating an amount of light in an optical path from the illumination source to the detector during the first measurement instance, wherein the optical modulation is performed by an optical modulation element that is a portion of the semiconductor wafer, wherein the optical modulation element is disposed in the optical path during the first measurement instance and the optical modulation element is not disposed in the optical path during the second measurement instance.

22. The method of claim 20, further comprising:
optically modulating an amount of light in an optical path from the illumination source to the detector during the first measurement instance, wherein the optical modulation is performed by a first optical modulation element that is not a portion of the semiconductor wafer; and
optically modulating an amount of light in an optical path from the illumination source to the detector during the second measurement instance, wherein the optical modulation is performed by a second optical modulation element that is not a portion of the semiconductor wafer.

23. A measurement system comprising:
an illumination source configured to generate a first amount of illumination light directed to a first measurement site on a surface of a semiconductor wafer during a first measurement instance, wherein a first instance of one or more structures under measurement is located at the first measurement site;
at least one detector having a planar, two-dimensional surface sensitive to incident light, the at least one detector configured to detect an amount of light collected from the surface of the semiconductor wafer in response to the first amount of illumination light and generate a first set of output signals indicative of the detected light during the first measurement instance;
one or more reflective optical elements disposed in an optical path between the illumination source and the at least one detector, wherein the optical path is incident on the surface of the semiconductor wafer more than once; and
a non-transitory, computer-readable medium storing instructions that, when executed by one or more processors, causes the one or more processors to:
determine an estimated value of a parameter of interest characterizing the one or more structures under measurement based at least in part on the first set of output signals.
